(19) United States
(12) Patent Application Publication
(10) Pub. No.: US 2023/0153477 A1
(43) Pub. Date: May 18, 2023

(54) Building Data Management System for Providing Operator Interface Processing and Displaying of Interrelated Hierarchical Building System Models

(71) Applicant: VueOps, LLC, San Francisco, CA (US)

(72) Inventors: Chidambaram Somu, Phoenix, AZ (US); Sushil Kumar, Noida (IN); Arundhati Ghosh, San Francisco, CA (US); James A. Arnold, San Francisco, CA (US)

(21) Appl. No.: 17/529,110

(22) Filed: Nov. 17, 2021

(51) Int. Cl. G06F 30/12; G06F 30/18; G06F 30/13; G06F 16/2457

(52) U.S. Cl. CPC G06F 30/12; G06F 16/24575; G06F 30/13; G06F 30/18

(57) ABSTRACT

Embodiments include an interface processing system for displaying interrelated hierarchical building system models. The interface processing system can include memory and a processor allocation to load an executable asset from a data store to instantiate an instance of a building management service that can receive from a client application executing an operator interface on a client device, a request to display a visual representation of an asset located in a building. The service can query an asset database including structured data associated with the asset. Location data can be used to generate a digital model of a building system location associated with the asset. The building management service can retrieve structured model data for the asset and system level components and extract, from a set of asset schemas, a hierarchical relationship between the asset, locations and the system level components to generate an interactive visual representation of the building system location.

### TECHNICAL FIELD

Embodiments described herein relate to systems and methods for interface processing of building system models and, in particular, to presentation and processing of documents related to building systems, locations assets, and building information modeling.

### BACKGROUND

Building managers are responsible for servicing and monitoring building structures, equipment, and other assets that provide service and utilities for a building, such as an office, factory, residential building, education building, hospital, storage facility, and so on. When issues arise with a building or the building’s equipment, a building manager usually performs an onsite investigation to troubleshoot the issue. This can include tracing a downstream effect back to a root cause, such as determining the cause of air conditioning shutting off in a particular office of a multitenant, multi-floor building.

Given the complexity and integrated structure of many building systems, identifying a root cause of an issue can be complex and time consuming. For example, inadequate air conditioning in an office of a particular floor of a multi-floor building can result from one or more issues with any one of a multitude of different systems, such as an electrical issue, water supply issue, outdoor cooling unit issues, compressor issues, distributor issue, ducting or other air flow control issue, among others. These systems can be spread-out throughout a building and span multiple floors, be located on the roof, in underground structures, and so on. Further, many components of the systems can be located within ceiling structures, in walls, or otherwise hidden from view. These factors make troubleshooting a complicated and time intensive process. As energy efficiency and reliability become more critical in building management, it may be desirable to have advanced tools for troubleshooting and/or maintaining buildings.

### SUMMARY

Embodiments described herein are directed to an interface processing system for displaying interrelated hierarchical building system, location, and asset models.

The system can include a memory allocation defined by a data store storing an executable asset and a working memory allocation, and a processor allocation configured to load the executable asset from the data store into the working memory allocation to instantiate an instance of a building management service.

The system can receive, from a client application executing an operator interface on a client device, a request to display a visual representation of an asset located in a building within a virtual building system model and query an asset database comprising structured data associated with the asset to determine location data for the asset and system level components associated with the asset.

The system can use the location data to generate a digital model of a building system location associated with the asset, where the digital model comprises a three-dimensional model of building structural components. The system can also retrieve model data for the asset and model data for the system level components and extract, from a set of asset schemas, a hierarchical relationship between the asset and the system level components.

In some cases, the system generates an interactive visual representation of the building system location comprising the three-dimensional model of the building structural components overlayed with visual representations of the asset and the system level components, and sends, to the client application executing on the client device, an interactive data set for displaying the interactive visual representation in the operator interface.

Embodiments described herein also include methods for generating interrelated hierarchical building system models. The methods can include receiving a request to display a visual representation of an asset located in a building within a virtual building system model, querying an asset database to determine location data for the asset and system level components associated with the asset, and using the location data to generate a digital model of the building, where the digital model comprises a three-dimensional model of building structural components.

The methods can include retrieving model data for the asset and model data for the system level components, extracting, from a set of asset schemes, a hierarchical relationship between the asset and the system level components, and generating an interactive visual representation of the building that includes the three-dimensional model of the building structural components overlayed with a visual representation of the asset and visual representations for the system level components.

Embodiments are further directed to methods for generating a structured data model that is used to display an interactive hierarchical model of a building system. The methods can include receiving a request to display a visual representation of the building system within a virtual building system model, where the request includes a building system type and a building system location.

The methods can include querying an asset database to identify assets that satisfy the building system type and the building system location and using the building system location to generate a digital model of the building system, where the digital model includes a three-dimensional model of building structural components. The methods can also include retrieving structured data for the assets that satisfy the building system type and structured data for system level components associated with the assets, and generating an interactive visual representation of the building system location including the three-dimensional model of the building structural components overlayed with visual representations of the assets and system level component associated with the assets.

The methods can further include causing the display of the interactive visual representation on a client device, receiving, from the client device, a selection of an asset of the assets displayed in the interactive visual representation of the building system location, and in response to the receiving the selection of the asset, causing the asset to be displayed according to a first rendering schema and other assets of the assets to be displayed according to a second rendering schema.

### BRIEF DESCRIPTION OF THE DRAWINGS

Reference will now be made to representative embodiments illustrated in the accompanying figures. It should be understood that the following descriptions are not intended to limit this disclosure to one included embodiment. To the contrary, the disclosure provided herein is intended to cover alternatives, modifications, and equivalents as may be included within the spirit and scope of the described embodiments, and as defined by the appended claims.

FIGS. 1A-1E show an example operator interface displaying a series of example interactive visual representations of a building system including visual representations of asset and system level components.

FIG. 2 shows a simplified system diagram for a building data management system that can generate an interactive building system model.

FIG. 3 shows an example building data management system for generating interactive visual representations of a building system including visual representations of asset and system level components.

FIG. 4 shows an example process flow for displaying interrelated hierarchical building system models.

FIG. 5 shows an example process flow for navigating building structures and systems.

FIG. 6 shows an example process flow for automatically defining location, system and asset relations for building structures and systems.

FIG. 7 shows an example process flow for automatically extracting, classifying and defining attribute values for building structures and systems.

FIG. 8 shows an example user interface for defining assets and system schemas for a building system model.

The use of the same or similar reference numerals in different figures indicates similar, related, or identical items.

Additionally, it should be understood that the proportions and dimensions (either relative or absolute) of the various features and elements (and collections and groupings thereof) and the boundaries, separations, and positional relationships presented therebetween, are provided in the accompanying figures merely to facilitate an understanding of the various embodiments described herein and, accordingly, may not necessarily be presented or illustrated to scale, and are not intended to indicate any preference or requirement for an illustrated embodiment to the exclusion of embodiments described with reference thereto.

### DETAILED DESCRIPTION

Embodiments disclosed herein are directed to a building data management system and methods for displaying interrelated hierarchical building system models. Embodiments described herein also relate to systems for retrieving and displaying information related to building assets and/or associated system components. The building data management system can be configured to render an interactive two-dimensional and/or three-dimensional models based on data from multiple disparate sources. The building data management system can render the interactive two-and/or three-dimensional model by using schemas to specify hierarchical, functional and other relationships between structured data objects associated with building systems and their assets.

The interactive two- and/or three-dimensional model (also referred to herein as interactive model) can display renderings of a building structure including foundation elements, floor, wall, and ceiling components, beams, columns or other structural features, roof elements, and so on. The interactive model can integrate renderings of various building systems in relation the building’s structural elements. For example, the interactive model can display a relation of systems such as heating, ventilation and cooling (HVAC) systems, electrical systems, plumbing systems, or other building assets or systems within a rendering of the building’s structural components. In this regard, the building data management system can display functional relationships between the various building structural features, systems, and assets.

In some cases, the building data management system can be configured to retrieve and/or store information resources related to building systems and/or building assets, which can include service documents, warranty information, spec sheets, and so on. Accordingly, a user viewing the interactive model can virtually view and navigate the various building structures, systems, and assets as well as pull up information such as service manuals for various assets without needing to locate and/or physically inspect building systems and building assets. These features of the building data management system, among others, may provide numerous benefits, such as decreasing troubleshooting time, increasing building efficiency, facilitating remote management, and so on, as described herein.

As used here the term “asset” and similar terms such as building asset refer to equipment that is located throughout a building or otherwise associated with a building and used to provide building services and/or functions that support building operations. Examples of assets include components and equipment that support building functions such as mechanical, electrical, plumbing, information/technology (IT), monitoring, emergency functions, and/or other building operations.

As used herein, the term “building system” and similar terms, refer to an integrated set of assets that function together to perform a specific function and/or service. Examples of building systems include mechanical systems, electrical systems, plumbing systems, IT systems, and so on.

For simplicity of description, the embodiments that follow reference mechanical, electrical, plumbing, and structural systems in an office building. However, this is merely one example and may not be required of all implementations of all architectures described herein. Further, although many embodiments that follow reference an office building, it may be appreciated that the systems and methods described herein can equivalently apply to other building types and/or building systems.

As construction of a building nears competition, the builder begins handoff procedures to transfer control of the building to the owner and/or building manager. Typically, the builder provides various information about the building to the owner/building manager that is used to manage and maintain the building going forward. This building information includes structural schematics and/or files showing the building structure such as foundation elements, locations of walls, columns, beams, ceilings, and other structural features.

The building information can also include as-built drawings and schematics for the various systems such as electrical, mechanical, plumbing, IT, and so on, which show the routing, location, and other information about these systems and the assets that make up these systems. The building manager can also receive copies of service manuals, warranties, or other information for various assets that are located throughout the building. All of these documents are typically provided to the owner/ building manager on a system-by-system basis. For example, the building manager may receive a set of structural schematics that show structural features of the building, a separate set of mechanical schematics that show mechanical systems, a separate set of electrical schematics, and so on. Accordingly, as issues arise, the building manager typically takes on the task of cross-referencing these numerous and sometimes disparate sets of documents to troubleshoot an issue and/or perform maintenance operations.

Further, over time, various assets or sub-systems may be replaced, upgraded, or otherwise changed out with different components. Accordingly, the original set of building data provided to the owner/building manager needs to be continually supplemented as changes to the building and equipment occur.

For example, if an air handling unit malfunctions, it may be replaced with a new air handling unit that is different from the original air handling unit, either by model, manufacturer, or type (or any other suitable difference). This may require modifying or rerouting electrical connections and/or upstream or downstream mechanical components such as ducting. In this regard, building system schematics tend to become outdated and inaccurate. All of these factors make it complex to maintain and troubleshoot issues that arise while managing a building.

The systems and methods described herein are directed to a building data management system for displaying interrelated hierarchical building system models. The system can include an operator interface that is used by a building manager to view interactive visual representations of a building system. These interactive visual representations can be generated from structured data about different building systems such as structural components, mechanical systems, electrical systems, plumbing systems, IT systems, and so on. In some cases, the system can use schemas to define relationships between the various building systems.

The building data management system can take as input a specification of the building domain model, which defines relationships between the assets, systems and building locations. The building data analysis system can also take as input instance data from a building information model or other sources. Using the building domain model and the instances data, the system can generate an integrated data model and instance data set(s) that defines location, hierarchal and/or functional relationships between the assets and system of the building. In this regard, the system can develop structural, location, functional, hierarchical between otherwise disparate data sets that supports generation and/or rendering of the interactive visual representations. The use of schemas to define the relationships between various building systems such as the building domain model help produce models and/or renderings for a building and its related systems that accurately reflect the actual, layout and functional relationships of the physical assets and systems within a building.

For example, the schemas can define attribute value pairs for assets and/or the different systems that is used to create an integrated building system model. As used, herein the term “building system model” refers to generated and derived data that defines the spatial, functional, hierarchical and/or other relationships between building components. The building system model can be formatted in a variety of ways and include data sets that are used to render the interactive two- and/or three-dimensional models that are displayed to a user in the operator interface. The building system models include formatted data sets to facilitate the display of system level and/or asset level components in a unified format that portrays the relative location and functional interrelation of the physical systems in the building. Accordingly, a user may interact with an operator interface to view a unified interactive model that can display these systems together. In some cases, the structured data for the various systems and/or assets can be associated with different layers of the interactive model. In this regard, a user may view subsets of these systems, individual systems, subsets of assets, and so on in isolation or in various selectable combinations.

For example, a user can select an electrical system layer to view a shaded and/or colored rendering of electrical components, while other systems are viewed in a second mode such as a partially transparent mode. Such viewing options can allow a user to highlight specific systems and/or assets and view hierarchical relationships of those assets such as upstream and downstream components that are associated with a specific asset or system.

In some cases, a user can interact with the operator interface to view a specific location of a building and/or the systems in that location or locations that provide services for it. For example, a building manager may be troubleshooting an air conditioning issue on a specific floor. The system can display that floor and views that include mechanical system components on that floor and their interrelation to other mechanical system components and/or other systems such as an electrical system. Accordingly, the system can help a building manager quickly identify and locate potential sources of the issue using a single interactive interface.

In some cases, the building data management system can include a building system and asset documentation database that stores, updates, and maintains information about building systems and assets. For example, the database can include digital data files such as service manuals, warranty information, model information, and so on. In some cases, these digital files can be accessed from an interactive building system model.

The interactive building system model can include options such as a menu, overlays, layers, or other interface elements that associate one or more digital files with a system or asset. For example, a user can view a three-dimensional model of the building’s structural components with a visual representation of a specific asset such as an air handling unit.

The interactive two- and/or three-dimensional model can include a user interface element such as a menu that displays information related to the air handling unit. This information can include an option to view a service manual, warranty information, or other digital files associated with the asset. In some cases, the interactive interface can display hierarchical/ functional relationships to one or more of the systems connected with the asset, that can be selected and viewed within the two- and/or three-dimensional model. For example, the interface can display which breaker the air handling unit is connected to, and selecting the electrical panel in the operator interface can allow the user to view information about the breaker, such as a digital service manual. In other cases, the operator interface can include search functions that allow a user to search for specific systems, types of systems, assets, types of assets, and so on.

The building data management system described herein can input the various system schematics and system information that are generated during construction and use system schemas to generate interrelated hierarchical building system models that allow the systems to be viewed together in an interactive interface.

As described herein, the building data management system can greatly reduce issue troubleshooting complexity and time by allowing a user to quickly view, isolate and locate related systems and assets within a building. Further, the building data management system can provide asset and system specific resources, such as digital service manuals that can be accessed from the interactive model.

The interactive building system models can be viewed on a client device, such as a tablet, smartphone, computer, or other device. Accordingly, the interactive model can be used in real time to locate specific assets and interconnected or intercoupled systems within a building and provide digital resources for addressing issues, maintaining assets, understanding the impact on building occupants of shutting down a building system(s) (e.g., for repair) and/or other building management functions.

In particular, a client device can be configured to execute a client application (also referred to as a frontend) configured to communicably intercouple with a host service (also referred to as a backend). The client application can render on a display of the client device a graphical user interface in which the interactive model is rendered. More specifically, the client application/frontend can be configured to communicate over one or more suitable protocols, over one or more networks (which may include the open internet), with the backend.

The frontend can submit a request to the backend that includes identifying information corresponding to a particular interactive model or entity associated with a particular interactive model. In response, the backend can send a response to the client application that causes the client application to modify the graphical user interface in a particular manner, such as changing a view of the interactive model or showing or hiding particular entities or portions of the interactive model. In other cases, the interactive model may be displayed, rendered, and controlled entirely on the client device by the client application. In yet other examples, the interactive model may be displayed, rendered, and controlled by the backend which, in turn, streams a user interface to the client application for display to a user.

It may be appreciated that these foregoing examples architectures are not exhaustive of the different architectures that may be suitable to implement a system such as described herein. For simplicity of description, the embodiments that follow may be understood to implement a request-response architecture, but a person of skill in the art may readily appreciated that this is merely one example.

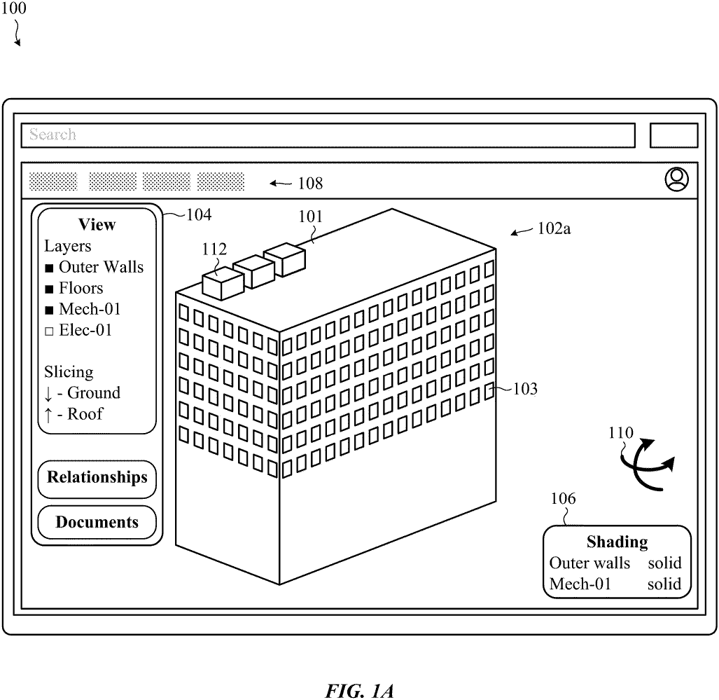

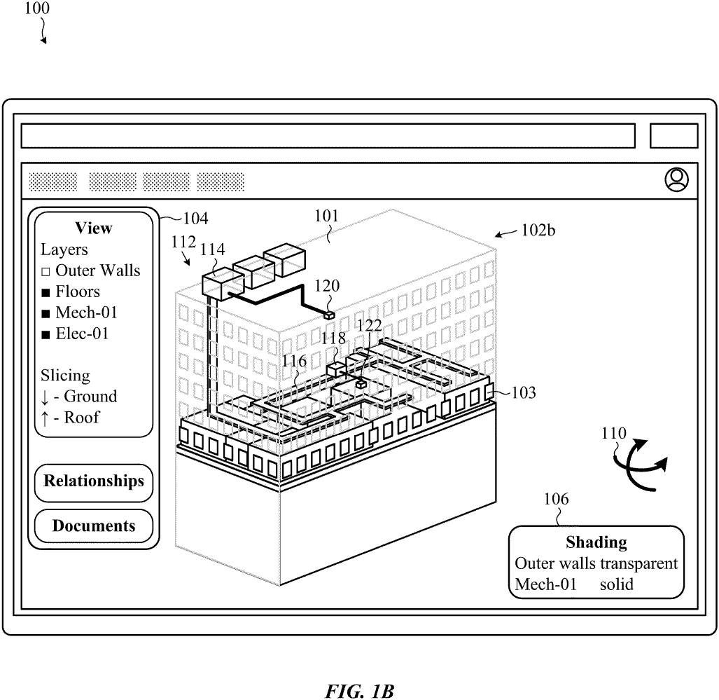

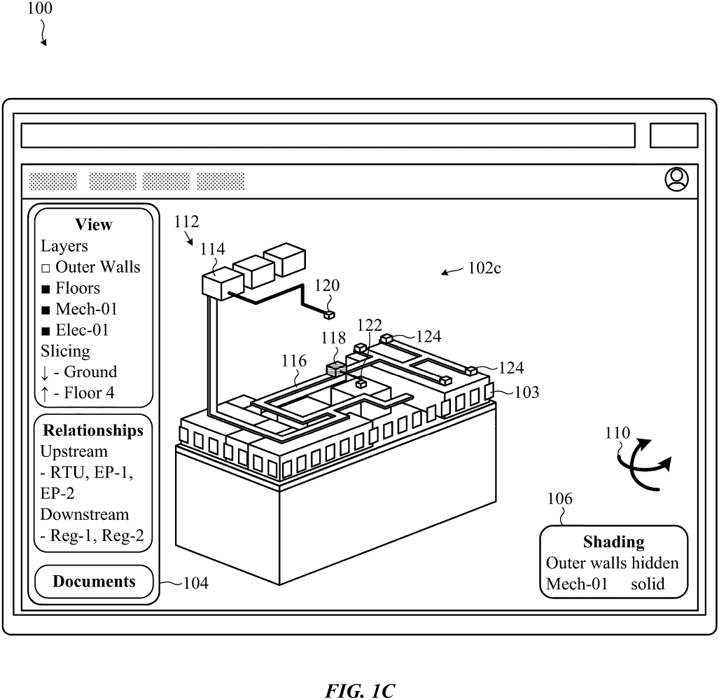

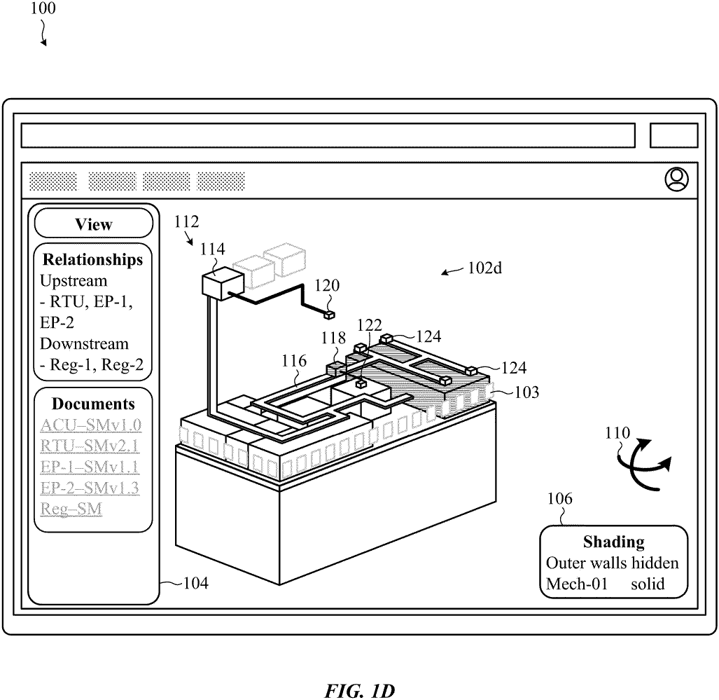

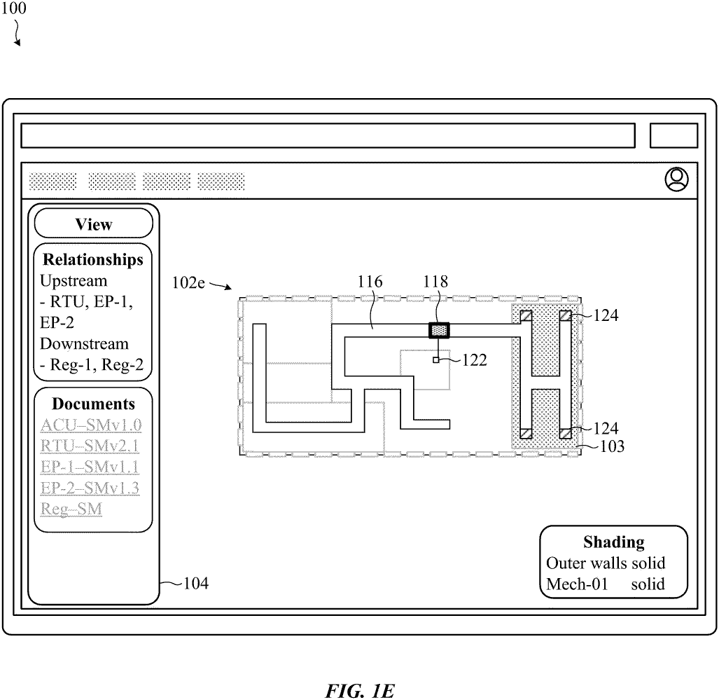

These foregoing and other embodiments are discussed below with reference to FIG. 1A-7. However, those skilled in the art will readily appreciate that the detailed description given herein with respect to these Figures is for explanatory purposes only and should not be construed as limiting.

In particular, FIGS. 1A-1D show examples of an operator interface 100 of a building data management system displaying interactive building system models. The examples shown in FIGS. 1A-1D illustrate an example set of model views that may be used to troubleshoot an HVAC issue for a specific location within a building.

The operator interface 100 may be rendered in a graphical user interface of a client device, such as a tablet computer, laptop computer, or cellular phone. In some cases, the operator interface 100 (and the corresponding graphical user interface in which the operator interface 100 is rendered) may be varied based on a display size and/or device type of the client device. In particular, the operator interface 100 as depicted may be rearranged and/or changed based on the electronic device/client device rendering the graphical user interface.

A client device as described herein can be implemented in a number of suitable ways. Generally and broadly, a client device includes a processor, a working memory, and a data store. In many cases, the data store may be leveraged to durably store one or more executable assets that can be loaded by the processor into the working memory in order to instantiate an instance of a client application configured to render the graphical user interface, including the operator interface 100, on a display of the client device. The client application can be configured to communicably couple to a backend service (also referred to as a host service) to obtain information, data, user preferences, or other data necessary or optional to render the operator interface 100.

The backend (not illustrated in FIG. 1A) can include a host application also referred to as a host service that executes as an instance of software over one or more physical or virtual resources, such as a processor allocation and/or a memory allocation. As with the client application described above, the host service instance can be instantiated in response to a processor allocation loading an executable asset from a durable memory or other datastore into a working memory. Once instantiated, the host service/backend can be configured to communicably couple to one or more client devices, such as the client device shown in FIG. 1A.

It may be appreciated that a “client application” instance and/or a “client device” or “frontend” supporting the same can be executed over, and/or instantiated in whole or in part over, any suitable computing resource. Similarly, it may be appreciated that a “host application” instance and/or a “host service” or “host server” supporting the same can be executed over, and/or instantiated in whole or in part over, any suitable computing resource.

As used herein, the term “computing resource” (along with other similar terms and phrases, including, but not limited to, “computing device” and “computing network”) refers to any physical and/or virtual electronic device or machine component, or set or group of interconnected and/or communicably coupled physical and/or virtual electronic devices or machine components, suitable to execute or cause to be executed one or more arithmetic or logical operations on digital data.

As described herein, the term “processor” refers to any software and/or hardware-implemented data processing device or circuit physically and/or structurally configured to instantiate one or more classes or objects that are purpose-configured to perform specific transformations of data including operations represented as code and/or instructions included in a program that can be stored within, and accessed from, a memory. This term is meant to encompass a single processor or processing unit, multiple processors, multiple processing units, analog or digital circuits, or other suitably configured computing element or combination of elements.

Example computing resources contemplated herein include, but are not limited to: single or multi-core processors; single or multi-thread processors; purpose-configured coprocessors (e.g., graphics processing units, motion processing units, sensor processing units, and the like); volatile or non-volatile memory; application-specific integrated circuits; field-programmable gate arrays; input/output devices and systems and components thereof (e.g., keyboards, mice, trackpads, generic human interface devices, video cameras, microphones, speakers, and the like); networking appliances and systems and components thereof (e.g., routers, switches, firewalls, packet shapers, content filters, network interface controllers or cards, access points, modems, and the like); embedded devices and systems and components thereof (e.g., system(s)-on-chip, Internet-of-Things devices, and the like); industrial control or automation devices and systems and components thereof (e.g., programmable logic controllers, programmable relays, supervisory control and data acquisition controllers, discrete controllers, and the like); vehicle or aeronautical control devices systems and components thereof (e.g., navigation devices, safety devices or controllers, security devices, and the like); corporate or business infrastructure devices or appliances (e.g., private branch exchange devices, voice-over internet protocol hosts and controllers, end-user terminals, and the like); personal electronic devices and systems and components thereof (e.g., cellular phones, tablet computers, desktop computers, laptop computers, wearable devices); personal electronic devices and accessories thereof (e.g., peripheral input devices, wearable devices, implantable devices, medical devices and so on); and so on. It may be appreciated that the foregoing examples are not exhaustive.

In many cases, the host service can be configured to manage user permissions, authentication, and/or other access controls prior to serving information to the client device of FIG. 1A to cause the graphical user interface to render the operator interface 100.

These foregoing descriptions of an example system architecture including a host service (backend) and a client device executing a client application (frontend) may be understood as a single example architecture, and not as limiting to a particular or specific preferred architecture. For simplicity of description many embodiments that follow reference a request-response architecture, but it may be appreciated that this is merely one example; the operator interface 100 can be rendered in a graphical user interface in a number of suitable ways over a number of configurations of suitable hardware.

These embodiments are provided in the context of a mechanical HVAC system to illustrate functionality of the building data management system and the concepts described herein can be readily applied to other systems or sets of building systems.

In FIG. 1A the operator interface 100 is displaying a first view 102a of a digital model of a building system 101 that was generated by the building data management system, as described herein. The digital model can include three-dimensional model data of structural components of the building system 101 such as floors, walls, ceilings, columns, beams, roof structure, aesthetic features/fixtures, and so on.

The digital model can also include model data for system level components such as mechanical systems, electrical systems, and so on. The operator interface 100 can also include various controls for viewing different building components of the digital model. For example, the systems view pane 104 displays options to view information related to the various building systems.

In the illustrated example, the systems view pane 104 includes options to view various layers of the digital model. In some cases, layers can correspond to different building structures, systems, assets, or other building elements. The layers controls can allow different structures, systems, and/or assets to be visible or hidden, which can allow a user to view various systems in isolation or selected combinations of systems or assets.

The systems view pane 104 can also include options to view various relationships of systems and/or assets. For example, if an asset is selected, the relationships option can display upstream and/or downstream systems associated with the selected asset, as described herein. The systems view pane 104 can also include a documents tab that can include documents such as service manuals associated with a specific asset and/or system. For example, if an asset is selected, the documents tab may display a service manual for the selected asset and/or service manuals for one or more upstream or downstream systems or assets.

In some cases, the operator interface 100 can include shading controls 106, which can be used to control how various structures, systems, assets, or other building components of the digital model are displayed. For example, the shading controls 106 may include options to display building structures as a solid model, which may hide components that are located behind or within these structures. In other examples, the shading controls 106 can include display options that control the transparency of various objects, the colors, the type of rendering such as wire-frame displays, and so on.

The shading controls 106 can be applied globally to specific building components, such as structural components, at a system level, at an asset level, and so on, or using combinations thereof. The operator interface 100 can also include navigation controls 110 that allow a user to view different perspectives of the building system 101. These can include rotational controls, zoom controls, pan controls, or any other suitable navigational controls. In some cases, the operator interface 100 can include other menu items 108 that provide additional functions such as changing view options, defining new views, importing additional data, saving digital views, printing functions, or any other suitable controls.

The operator interface 100 can be used by a building manager to troubleshoot issues that arise with various systems and/or assets. For example, a building manager may receive a notification that the air conditioning in an office 103 has stopped working. However, there are numerous potential causes of this issue. In the illustrated example, the operator interface 100 can display the first view 102a of the building system 101. In some cases, this may be a default view of the building system 101 that shows an overview of the building system 101. The operator interface 100 can be used to select and/or search for one or more specific systems and/or assets. For example, the building manager can select an air handling system 112 that is associated with the location of the office 103 in which the air conditioning has stopped working.

In some cases, selecting a specific system or asset, such as the air handling system 112, can change the view of the building system to highlight or emphasize the selected system in the operator interface 101, for example, as shown in FIG. 1B, selecting the air handling system 112 of a second view 102b to be displayed in the operator interface 100. The second view 102b can display the building’s structure in a transparent view and the air handling system 112 in a solid view. In this regard, the assets and other components of the air handling system 112 can be viewed in relation to their position within the building system 101. For example, the air handling system 112 can include a roof-top unit 114, ducting 116, an air controller 118, a first electrical sub-system 120 for the air handling system 112, and a second electrical sub-system 122 for the air controller 118.

The second view 102b can show the placement of the assets and/or other components of the air handling system 112 relative to various building structures. For example, the second view 102b can show the positioning of the roof-top unit 114 on the roof and/or the positioning of the roof-top unit 114 with respect to other roof-top units that serve other portions of the building system 101.

Additionally or alternatively, the second view 102b can show the routing of the ducting 116 through the building, the location of the air controller 118, and the location of various sub-systems that are associated with the air handling system 112, such as the first and second electrical sub-systems 120, 122. Accordingly, the building manager can interact with the operator interface 100 to identify, view, and locate various systems that service a particular location in the office such as the office 103. This information can increase the efficiency of troubleshooting an issue, by providing the integrated three-dimensional model that shows the location of the systems and assets within the building system 101.

In some cases, the operator interface 100 can include options for hiding the building system’s 101 structural components such as walls, floors, ceilings, and/or subsets of these components. FIG. 1C shows an example of hiding structure components that are located above the floor that the office 103 is located on (e.g., Floor 4). This allows a user to view the air handling system 112 and its associated subsystems to be viewed in isolation. In some examples, the user such as the building manager can select a specific asset such as the air controller 118, which the building manager may suspect as contributing to the air conditioning issue in the office 103.

In response to selecting the air controller 118, the system view pane 104 can be updated to identify specific assets and/or systems that are related to the air controller 118. For example, the “Relationships” pane can display the hierarchical relationships of the related systems and/or assets. As illustrated in FIG. 1C, the “Relationship” pane can display “Upstream” components, which can be used to designate components that provide inputs to the air controller 118. In the illustrated example, the “Upstream” component can include an “RTU” element which corresponds to the roof-top unit 114, an “EP-1” element which corresponds to the first electrical sub-system 120, and an “EP-2” element which corresponds to the second electrical sub-system 122.

The “Downstream” components can include assets and/or systems that are supplied by the air controller 118 such as a “Reg-1” element and a “Reg-2” element which correspond to registers 124, two of which are labeled for clarity. In some cases, the Upstream and Downstream elements (e.g., RTU, EP-1, Reg-1, etc.) can be selectable interface elements, and selecting one or more of these elements can update the operator interface 100 to view the relationships related to these elements. Additionally or alternatively, these interface elements can link to digital resources associated with these assets. For example, selecting the EP-2 element can cause a service manual for the second electrical sub-system 122 to be displayed in the operator interface 100.

FIG. 1D shows an example of where the operator interface 100 displays a fourth view 102d that includes documents for the systems and/or assets that are associated with the selected air controller 118. For example, the system view pane 104 can include a “Documents” pane that includes references and/or links to digital resources associated with a selected asset and/or system, such as the air controller 118. For example, the Documents pane can include a link to a digital copy of the service manual for the air controller 118 (e.g., ACU-SMv1.0), and selecting this link can cause the operator interface 100 to display the service manual for the air controller 118.

When the building manager receives an indication that the air conditioning in the office 103 has stopped working, he or she can interact with the operator interface 100 to view and locate the relevant systems. In this example, the building manager may determine that all office spaces that are downstream of the air controller 118 have lost air conditioning. In this regard, the building manager can select the air controller 118 element displayed as part of the building system model to view the assets and or systems associated with this air controller 118. Accordingly, the building manager can use the building system model to determine the location of the air controller 118 and inspect the air controller without having to first inspect the office space 103 and/or building schematics to trace the office 103 back to the air controller 118. Further, upon inspection of the air controller 118, the building manager may determine that there is no power being supplied to the air controller 118. The building manager can use the building system model to determine that the second electrical sub-system 122 provides electrical power to the air controller 118.

From the operator interface 100, the building manager can view the location of the second electrical sub-system 122 and can access a digital copy of a service manual for the second electrical sub-system 122. Accordingly, the building manager can inspect the second electrical sub-system 122 without needing to find and decipher the buildings electrical schematics and cross-correlate these with the HVAC system schematics.

FIG. 1E the operator interface 100 is displaying a two-dimensional view 102e of a digital model of a building system that was generated by the building data management system, as described herein. The two-dimensional view 102e can include two-dimensional model data of structural components of the building system 101 such as floors, walls, and so on. The two-dimensional model view can also include a two-dimensional view of the model shown in FIG. 1D, and include the ducting 116, the air controller 118, the second electrical sub-system 122, and registers 124, among other components, as described herein.

The two-dimensional view can permit a user to view an existing drawing (e.g., pdf technical drawing), add markers on an overlay of 2D drawing and index the markers to the data model. This permits the user/operator to ‘digitalize’ existing building as-built drawings. In this regard, the a suer may leverage existing content (e.g., building, system and/or asset schematics) and define relations for this content that correlate it with building locations, assets and systems, which can be displayed as part of an integrated model in the operator interface 100.

As illustrated in FIGS. 1A-1D, generation of an integrated building system model can be used to display an interactive model of the building system that can be used to troubleshoot an issue. The integration of a building’s structural components, systems, and assets into a digital model that includes the physical location of these systems and their hierarchical relationships can increase the efficiency of building systems by reducing the time it takes to troubleshoot an issue, which can reduce the time assets and/or systems are down when issues arise.

These foregoing embodiments depicted in FIGS. 1A-1D and the various alternatives thereof and variations thereto are presented, generally, for purposes of explanation, and to facilitate an understanding of various configurations and constructions of a graphical user interface and a system for generating and updating the same, as described herein. However, it will be apparent to one skilled in the art that some of the specific details presented herein may not be required in order to practice a particular described embodiment, or an equivalent thereof.

Thus, it is understood that the foregoing and following descriptions of specific embodiments are presented for the limited purposes of illustration and description. These descriptions are not targeted to be exhaustive or to limit the disclosure to the precise forms recited herein. To the contrary, it will be apparent to one of ordinary skill in the art that many modifications and variations are possible in view of the above teachings.

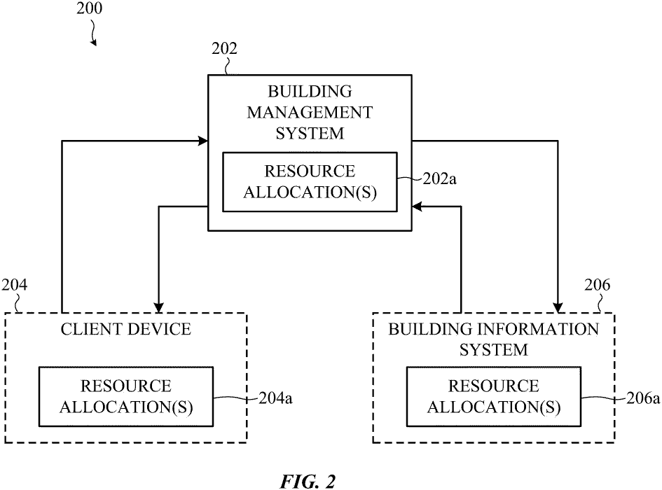

FIG. 2 shows a simplified system diagram 200 for building data management system 202 that can generate an interactive building system model, as described herein. To perform the functions described herein, the building data management system can implement a client-server architecture in which a host server or service associated with the building data management system receives requests from and provides responses to (some or all of which may comply with a communication protocol such as HTTP, TCP, UDP, and the like) one or more client devices, each of which may be operated by a user of the building data management system.

In other cases, a request-response architecture may not be required, and other communication and information transaction techniques may be used. For simplicity of description, examples that follow reference a request-response architecture, but it may be appreciated that different building data management systems may be configured to serve and/or host information, including team-generated content, in a number of suitable ways.

A host server or server system supporting one or more functions of a building data management system such as described herein can serve information, including interactive digital models of building systems, to a client device and, in response, the client device can render a graphical user interface on a display to present at least a portion of those interactive digital models to a user of that client device.

More specifically, a server system that includes a memory allocation and a processor allocation can instantiate an instance of a building data management system, as described herein. Once instantiated, the building data management system can be configured to receive API requests from a client device, from other collaboration tools, or from a bridge service as described herein.

The system diagram 200 can include the building data management system 202 that interfaces with a client device 204 and a building information system 206. Each of the building data management system 202, the client device 204, and the building information system 206 can be configured to operate as an instance of software independently instantiated over a server system. In some cases, one or more of the building data management system 202, the client device 204, and the building information system 206 may be instantiated over the same physical resources (e.g., memory, processor, and so on), whereas in other cases, each of the building data management system 202, the client device 204, and the building information system 206 are instantiated over different, independent, and distinct physical hardware.

As the manner by which the building data management system 202, the client device 204, and the building information system 206 are instantiated can vary from embodiment to embodiment, FIG. 2 depicts each of the building data management system 202, the client device 204, and the building information system 206 as supported by dedicated resource allocations. In particular, the building data management system 202 is supported by the resource allocation 202a, the client device 204 is supported by the resource allocation 204a, and the building information system 206 is supported by the resource allocation 206a.

As with other embodiments described herein, the resource allocations supporting the building data management system 202, the client device 204, and the building information system 206 can each include a processor allocation and a memory allocation. The processor and memory allocations may be static and/or may be scalable and dynamically resizable.

In many embodiments, the memory allocations of the building data management system 202, the client device 204, and the building information system 206 include at least a data store or other database and a working memory allocation.

As a result of these constructions, each of the building data management system 202, the client device 204, and the building information system 206 can be instantiated in response to a respective processor allocation accessing from a respective data store at least one executable asset (e.g., compiled binary, executable code, other computer instructions, and so on). Thereafter, the processor allocation can load at least a portion of the executable asset into the respective working memory allocation in order to instantiate respective instances of the building data management system 202, the client device 204, and the building information system 206.

Once each of the building data management system 202, the client device 204, and the building information system 206 are instantiated, the building data management system 202 can be configured to communicably couple to the client device 204 and the building information system 206.

More specifically as noted above, in many cases the building data management system 202 is configured to communicate with the client device 204 and the building information system 206 according to a request/response architecture. This, however, is not a required implementation. In other embodiments, a subscription/publication communication model may be implemented.

Various embodiments of the building management system are described herein are described with respect to relational databases. The building management system can also be implemented using other data structures such as a graph data structure in which building data can be stored in a graph structure that includes relational data organized in node and edge structures.

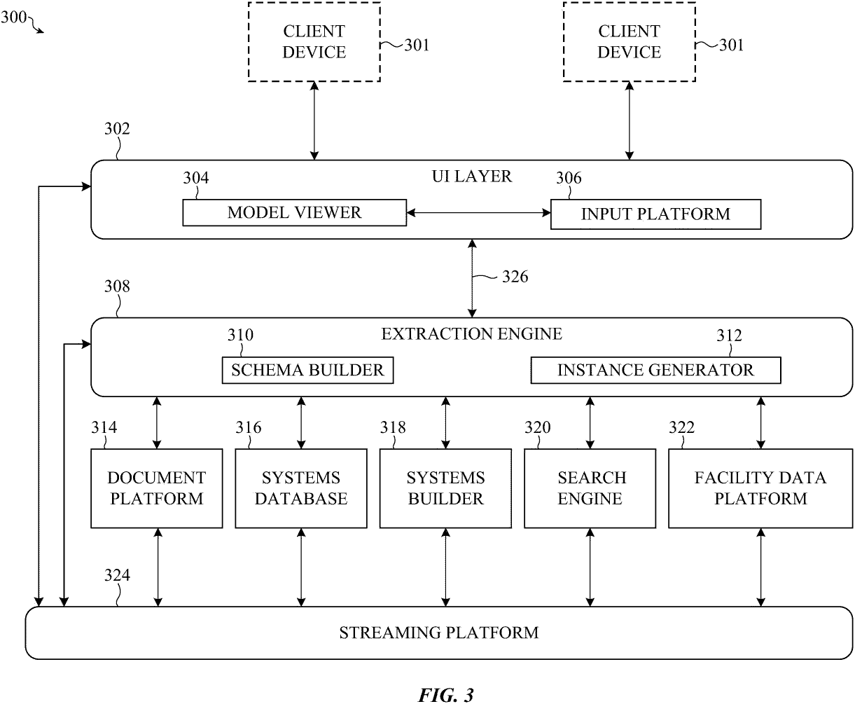

FIG. 3 shows a simplified architecture for a building data management system 300 for generating interactive visual representations of a building system including visual representations of asset and system level components as described herein. The building data management system 300 can be an example of the building data management systems described herein and can include a user interface (UI) layer 302, an extraction engine 308, and a streaming platform 324. These components of the building data management system 300 can be communicably coupled via one or more communication links 326 (one of which is labeled for clarity), which may be implemented as any suitable wired or wireless data transfer connection.

The building data management system 300 can be implemented as a platform that provides a system for various users such as building managers to retrieve, view, and interact with digital models of a physical building system. As described herein, the building data management system 300 can generate integrated three-dimensional building system models that display structural components along with other system level components such as mechanical (HVAC) systems, electrical systems, plumbing systems, and IT systems according to their physical, hierarchical, and their functional interrelations.

The UI layer 302 can include a model viewer 304 that performs display processing for the interactive digital models described herein and displayed in an operator interface of a client device 301, and an input platform 306 that processes user inputs at the operator interface. The UI layer 302 can interface with one or more client devices 301 to display graphical user interfaces of the building data management system on various client devices 301.

The UI layer 302 can receive and process user inputs from a client device 301, communicate with other portions of the collaboration system such as the extraction engine 308, the streaming platform 324, and/or other services, and update the client device 301 accordingly.

The model viewer 304 can be configured to display two-dimensional and/or three-dimensional building systems models such as two-dimensional and/or three-dimensional renderings, CAD models, and/or other parameterized model data. The model viewer 304 can update model views, for example, based on user inputs processed by the input platform or in response to other inputs. The model viewer 304 can include and/or interface with a geometric modeling kernel, CAD viewer, or other three-dimensional modeling engines. In some cases, the model viewer 304 can include software and/or hardware viewing components that are licensed from third-party suppliers, and use the models generated building data management system 300 to produce the visual renderings, CAD models or other parametrized model data.

The model viewer can support various viewing and/or rendering functions such as panning, zooming, rotating, or other movements of a three-dimensional model; updating view setting such as coloring, lighting, shading, transparency and so on; and/or hiding, adding, or otherwise updating which component, assets, systems, and structures are shown in a digital model. Additionally or alternatively, the model viewer can update one screen control, for example, based on options available to a user. In some cases, the model viewer 304 can update other view elements such as the systems view pane 104, shading pane 106, and so on.

The input platform 306 can process inputs received at the operator interface and generate outputs in response to the inputs. For example, the input platform 306 can be configured to process various types of commands, search functions, and selections of model components, such as specific assets and/or systems. In response to receiving the inputs, the input platform 306 can generate commands, requests, or other functions that update the interactive visual display and/or model components based on the type of input.

Generally and broadly, the extraction engine 308 retrieves building data from designs, constructions, and other building models and documents and uses schemas to define the relationships between building structural features and assets, systems, and other components. The extraction engine 308 can include a schema builder 310, and an instance generator 312, which function together to generate digital models of a building system that are used to create the interactive visual representations/models that are displayed on the client devices 301.

The schema builder 310 can define product schemas such as those received from a facility data platform 322 and support creation of domain entities that are used to define parameters of a building system model. For example, the schema builder 310 can define location parameters for structural components, assets, and systems, which include building identifications, level/floor data, zone data, room/space, height, and so on. In some cases, location data can include connections between various components such as an asset’s connection to a building structure (e.g., ceiling girder). For example, the location data can include an asset’s location within a room, the area served by the asset and/or an area impacted by the asset, for example, in cases were an incident that impacts an asset’s performance or causes the asset to be shut down for repair or replacement.

The schema builder 310 can define product level features, such as part identifiers, such as having a unique identifier and/or instance tag value/serial number; and components that are constituent to a product, but may not have a unique identifier; connectors, which can be defined as a member of a system or assets, such as items like duct work, registers, and so on. The schema builder 310 can also include assets, which can be a part that is uniquely identified and associated with a specific system and location within a building.

The schema builder 310 can also include assembly data, which can relate to an asset and/or group of parts that form an asset, and building system data, which includes assemblies of assets, components, connectors, and/or the like. In some cases, the schema builder 310 can also include classifications that define the hierarchical relationship of the various assets, systems, and structures within a building. The schema builder 310 can also include classifications that define the hierarchical relationship of various semantic concepts described by the system, for example a product, location, or system classification taxonomy.

The instance generator 312 can be configured to receive building data and generate and update building system models, for example in response to user interaction with a visual representation of the building system at an operator interface. For example, the instance generator 312 can be configured to update assets, systems, and their interconnections.

The extraction engine 308 can interface with one or more support systems, services, database, or other resource, which provide building information, asset data, system data, and other information that is used to construct the building system models. These components can include a document platform 314, a systems database 316, a systems builder 318, a search engine 320, and a facility data platform 322.

The document platform 314 can access documents that are associated with building assets and systems and extract data from the documents to support document searching, retrieval, and viewing of digital documents stored in any number of suitable data stores, whether local or remote and/or whether first party or third party. For example, the document platform 314 may be configured to communicably couple to a third party storage service, such as a remote FTP service. In other cases, the document platform 314 may be configured to couple to an email host, such as via IMAP or POP3, in order to retrieve documents attached to emails. For example, a building manager may authorize the document platform 314 to access emails directed to a building email account such that the document platform 314 can search and retrieve documents and updates to documents relevant to building-owned assets.

For example, a building manager may install a new asset and register the product with a manufacturer of the product. From time to time the manufacturer may send emails with attachments or body content relevant to maintenance, servicing, and/or replacement of the new asset; as a result of accessing the building email account, the document platform 314 can access each of these emails (and documents referenced, linked, or attached thereto).

In another example, a building manager may leverage an account with a local or remove document storage server or service. The document platform 314 can be privileged to access this account to retrieve documents (and/or references to documents, such as identifiers) therefrom. In this regard, the document platform 314 can enable accessing remote documents and passing them to a document processing system that can que several content processing jobs. This can support document searching and finding of relevant content including index file names, generating thumbnail images of the various pages (e.g., a first page of a document) and/or indexing document content. In some cases, the document processing system is extensible and/or scalable such that additional jobs can be added and queued, and tasks performed such as optical character recognition (OCR) or other language processing techniques that support automated document classification.

The document platform 314 can be configured to access any suitable document, in any suitable format. The document platform 314 can include and/or may be communicably coupled to a document format conversion service configured to convert between formats. In some cases, the conversion service may be configured to analyze the content of documents accessible to the document platform 314. For example, the conversion service and/or another portion of the document platform 314 may be configured to perform an OCR operation that results in a searchable text layer being created for an otherwise rasterized document. In other cases, the conversion service can be configured to perform image analysis to compare portions of a particular document to known geometries of objects rendered in a building model, such as described above. In this regard, the document platform 314 can be support scalable and extensible document processing services.

For example, the document platform 314 and/or the conversion service may be configured to identify that AC UNIT 1 as an entity within a digital building model approximately matches the shape of a line drawing or photograph extracted from a digital manual of the same AC unit. Based on this determination other data fields stored by another database (e.g., a systems database, described below) of the building data management system 300. For example, once a document or a page or image extracted from a particular document and an object in a building model are identified as describing the same physical asset (whether manually or automatically), data extracted from the document can be used to populate one or more databases of the building data management system 300. Information that can be extracted from a document that can be used to populate a database of the building data management system 300 includes, but is not limited to: dimensions; parts; model numbers; manufacturer; manufacture date; warranty type; warranty expiration date; warranty start date; installing contractor; installation operations; maintenance schedules; servicing schedules; and so on.

In yet other examples, the document platform 314 can be configured to retrieve documents by searching one or more third party search engines. For example, the document platform 314 can be configured to automatically retrieve a manual for a particular asset having a particular model number by searching for PDF documents referencing the model number and product type. A person of skill in the art may readily appreciate that any suitable number of techniques may be leveraged to automatically retrieve documents from a third party service (e.g., via API, via query, and so on).

The foregoing examples are not exhaustive of the uses or functions of a document platform, such as the document platform 314, as described herein. Generally and broadly, it may be appreciated that the document platform 314 can receive and/or store and/or access any suitable number of documents, stored on any suitable platform or in any suitable database. Documents can include text content, multimedia content, 3D model content, or any other suitable content. Thereafter, data may be extracted from the document in any suitable manner (e.g., artificial intelligence identification/tagging of document parts, semantic analysis, regular expressions, and so on).

In some cases, extracted data can be used to generate digital copies of documents (or abbreviated summaries thereof) associated with various assets and systems, and/or for performing search functions related to specific documents. Example of documents can include model files, such as CAD models (e.g., two-dimensional and/or three-dimensional CAD models), building information models (BIM), media such as images, movies, gifs, links to first or third party hosted content, editable text documents, and so on.

The systems database 316 can store location, asset, system, and building structural data extracted by the extraction engine 308. The systems database 316 can also store document data such as metadata that identifies specific documents and/or relates documents to specific systems and/or assets.

The systems builder 318 can take as input document data, such as model data (e.g., model information such as part identifications, serial numbers, location data, asset specifications, three dimensional model, and so on), and generate functional, geometrical, and/or hierarchical relationships between instance data and checking these relationships for compliance with a facility data specification, which can define relationships between various assets, systems, building structures, and/or other components.

The search engine 320 can communicably couple to the systems builder 318, the document platform 314, the systems database 316 and/or any other data source of the building data management system 300 and can index the data retrieved therefrom (or stored thereby). In this manner, all data and information associated with a particular building, no matter where stored, can be uniquely indexed in a searchable manner. Any number of suitable indexing or search systems can be used. One example search indexing methodology is Elasticsearch, although this is merely one example.

The search engine 320, once content of the building data management system 300 is indexed, can be queried in real time to obtain results relevant to that query. A query may be automatically generated by a graphical user interface, such as a graphical user interface rendered on a client device and in communication with the UI layer 302 and the model viewer 304. In other cases, a query may be manually submitted based on user input received from a user of a client device. In response, the search engine 320 can return a result with information identifying relevant sources, such as documents, service schedules, maintenance schedules, or model entities and so on.

The facility data platform 322 can store facility data specifications related to one or more buildings. The facility data platform can specify location, asset and system schemas for a building system. The facility data platform can also include classification taxonomies that define concepts and relationships such as hierarchical relationships of product categories and relationships between assets and systems, such as which physical assets are members of which building systems (water systems, HVAC systems, electrical systems, and so on).

As a result of this construction, a building manager operating a client device to view a model of a building can click a single asset rendered in the UI. In response to this user input, a query can be submitted to the search engine 320 that, in response, can return all documents and upstream and downstream model entities (and documents associated therewith) that are associated with the selected asset. In other words, simply by interacting with the user interface of the client device, the building manager can be presented with all relevant information -information about service schedules, maintenance schedules, current status (e.g., from the facility data platform or a building information system, such as the building information system of FIG. 2), upstream systems and assets, downstream systems and assets, and so on. As a result of these configurations, building issues and trouble/maintenance tickets can be addressed in a substantially more efficient manner.

In other cases, the search engine 320 may be configured to provide documents and/or tailor search results bases on location data for a user. Location data for a client device may be used to perform and/or refine search results. For example, if a user is located at a particular location within a building, the search engine may use this location data to refine search results, for example to show documents and/or other information that is related to assets and systems in that location.

As a result of the increased speed and efficiency with which building issues can be addressed, potential damage to downstream systems and locations that may occur if issues are not addressed quickly (e.g., flooding, overheating, under/over powering, and so on), can be mitigated, thereby extending the service life of substantially all building assets.

Additionally or alternatively, the architecture for a building data management system 300 can utilize or be implemented within a serverless computing architecture such as an event-driven compute service that lets you run code for virtually any type of application or backend service without provisioning or managing servers.

These foregoing embodiments depicted in FIG. 3 and the various alternatives thereof and variations thereto are presented, generally, for purposes of explanation, and to facilitate an understanding of various configurations and constructions of a system configured to ingest, process, validate, and display building-related, such as described herein. However, it will be apparent to one skilled in the art that some of the specific details presented herein may not be required in order to practice a particular described embodiment, or an equivalent thereof.

Thus, it is understood that the foregoing and following descriptions of specific embodiments are presented for the limited purposes of illustration and description. These descriptions are not targeted to be exhaustive or to limit the disclosure to the precise forms recited herein. To the contrary, it will be apparent to one of ordinary skill in the art that many modifications and variations are possible in view of the above teachings.

For example, although not referenced above, it may be appreciated that the embodiments described herein can be further extended to couple to issue tracking systems (trouble ticket systems), building automation systems, tenant alert/communications systems, access systems, people mover systems, scheduling systems, notification systems, work assignment systems, emergency shutoff systems and so on.

For example, a building may include an air handling unit serving a particular branch of an HVAC system may be associated with a particular electrical circuit and a particular water supply line and water pump. In some cases, the water pump may fail which in turn may result in a water leak impacting areas below the air handling unit and an environmental issue (due to failed air handling) at exit points of the effected branch of the HVAC system.

Under conventional management, the flooding issue may be noticed after the environmental issue. The environmental issue may be reported by a tenant, whereas the flooding may only be noticed during a maintenance walk-through sometime later in the day. Upon receiving a report of an environmental issue, the building manager may navigate to the affected area, begin back-tracing the ductwork taking temperature and/or humidity and/or airflow readings until the particular branch is identified as a potential cause of the reported problem. After some time of diagnosing this issue, the conventional management checklist may finally identify that the air handling unit is not functioning properly, after which maintenance personnel may be sent to investigate. Such personnel will likely notice flooding, and may authorize an emergency shut off water to all air handling units, including the flooded the air handling unit, in order to prevent further damage.

This may, in turn, effect environment for a larger number of tenants of the building. In some cases, turning off water without also turning of electrical power to the air handling units may cause damage to the air handling units and/or other downstream systems, such as a networking room that depends on reliable air circulation to maintain performance. In this example, once a flood is noticed, priority of response changes - maintenance personnel focus attention to flood damage mitigation over addressing the first-reported maintenance issue.

During this re-focus of attention, temperature may rise in one or more networking rooms, in turn necessitating an automatic shutoff of networking equipment, in turn shutting down building access control systems, building elevators, and building communications. At a later time, all systems may be slowly brought back online as maintenance may eventually correctly diagnose that the water pump of the air handling unit has failed. As known to a person of skill in the art, during this time period, one or more other systems may be irreparably damaged and/or may require replacement or further maintenance before being brought online again. In some cases, maintenance may simply replace the entire air handling unit, instead of correctly diagnosing the root cause of all downstream problems.

By contrast, a system as described herein may be used by a building manager to select, in a building model user interface, the tenants, floors, rooms or rooms reporting the environmental issue. In response, a query is generated automatically to the search engine which returns all downstream and upstream systems, and all documentation and information relevant to those systems and their constituent parts.

The user interface can be updated to show only the air handling unit and its constituent parts, including the water pump, and impacted systems, such as the electrical circuit and the water line supplying the water pump. In addition, the search engine can return relevant documents and data, such as maintenance documents and warranty documents for each of these displayed systems and parts. With this information aggregated together, the system may further highlight for the building manager that the water pump has not been serviced according to its recommended service schedule. The system may further display, for the building manager, a link to a forum post noting that the water pump of this particular model number fails at a higher than normal rate, which may result in a loss of pressure and flooding. In some embodiments, terms like “flooding risk” (or other high priority risks) may be visually emphasized for the building manager.

All this information can be visually aggregated for the building manager substantially instantaneously in response to the building manager’s input. In some cases, the building manager may not provide input at all; the system may be configured to display (and/or hide) select information in response to a trouble ticket being selected by the building manager.

Regardless of how a particular problem is identified (e.g., after simply providing an input that a particular tenant reported an environmental issue), the building manager can immediately note that a potential cause of the environmental issue is a water pump failure in a particular air handling unit, which may also lead to flooding. In response to noting this potentially damaging issue, the building manager may determine that verifying operation of the water pump is a top priority before all other diagnostic steps.

For example, the building manager may send a first maintenance technician to investigate whether the water pump has failed, and may send a second maintenance technician to a water control valve to be ready to shut off water to the water pump in case the water pump has failed. Upon determining that the water pump has failed, the first technician can radio to the second technician to disable the specific water control line feeding the water pump and radio to a third technician to cut power to the air handling unit while the water pump is replaced.

A person of skill in the art can readily appreciate that by leveraging a system such as described herein, a likely cause of the reported issue can be readily or immediately identified, which in turn substantially mitigates any potential damage slower diagnosis (e.g., flooding). In a more simple phrasing, systems described herein allow a building manager to quickly triage and prioritize problem/issue diagnostic steps by visually aggregating all relevant information in a three dimensional model of the portion(s) of the building the can be impacted by a particular trouble ticket. This saves both time and money, and minimizes downtime of impacted systems while repairs are conducted.

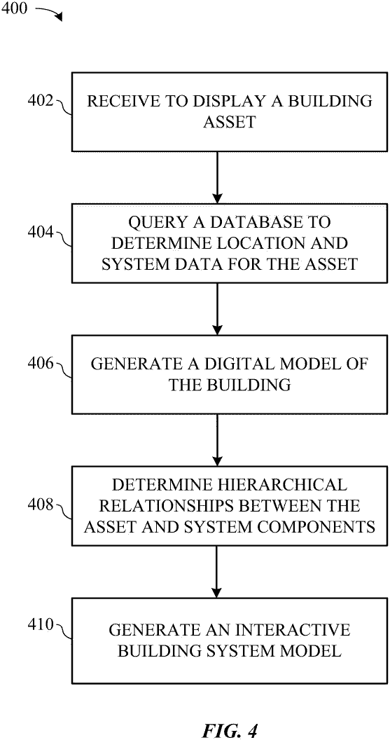

FIG. 4 shows an example process 400 for displaying interrelated hierarchical building system models. The process can be performed by the systems described herein such as the building data management system.

At operation 402, the process 400 can include receiving a request to display a visual representation of a building asset within a virtual model of the building. In some cases, the request can be received at an operator interface on a client device and include identification of a building and an identification of an asset located within the building. The identification of the asset can include a specific asset ID such as a serial number or other unique identifier for the asset. In other cases, the identification can include an asset type or category.

For example, a user can input a request into the operator interface to view all air handling units. In some cases, the request can include text, voice, and/or other inputs. For example, a user may take a picture of a specific asset and/or serial number on the asset and the building data management system can perform text and/or image analysis to identify the asset. In some cases, the request can be a system level request that identifies a particular system or subsystem. For example, the request can be to display all HVAC components for a building.

At operation 404, the process 400 can include querying an asset database to determine location data for the asset and system level components associated with the asset. For example, the extraction engine 308 can access one or more services and/or databases to retrieve asset information and determine a location of the asset within the building structure. The asset information can be used to identify a system that the asset belongs to.

For example, if the asset is an air controller, operation 404 can include identifying that the asset is part of the HVAC system. In some cases, this can include identifying one or more sub-systems for an asset, for example, determining from the asset information, that the air controller services a specific location within the building. Using the system data, operation 404 can include identifying other assets that are part of the HVAC system and/or sub-system of the asset. For example, the extraction engine 308 can access services, such as the systems database 316, the facility data platform 322 and so on to identify assets from a common system such as an HVAC system.

Operation 404 can include retrieving model data for the asset and model data for the system level components. In some cases, an asset database may store model information about an asset which can include structured data models for the assets, such as a three-dimensional Building Information Model (BIM), a computer-aided design (CAD) model, drawings such as two-dimensional asset or system drawings, or the like. In some cases, the asset information can include an input and output specification, such as an electrical input requirement, an output specification, and so on.

In some cases, the asset information can include specifications for structural connections to the building’s structures. In other cases, the asset information can include specifications on the connections and/or other components that are connected to a specific asset, such as ducting components, plumbing input and/or output components, electrical connectors, wiring, and/or any other suitable components. In some cases, the interrelation of these is obtained from analyzing the asset specification, and/or other resources such as the facility data specification, user defined parameters, and so on.

At operation 406, the process 400 can include using location data for an asset to generate a digital model of the building. The digital model can be a three-dimensional model of building structural components such as foundation elements, columns, beams, floors, walls, and ceiling components, windows, and/or other structural features.

In some cases, the digital model can be created for the entire building structure. In other cases, the digital model can be created for a specific portion of the building that is associated with the specific asset, sub-system, or system (e.g., a filtered view that satisfies specific use cases such as incident response, first responders, and so on as described herein). Continuing with the air controller example, operation 406 can include determining where the air controller is located within the building. In these cases, the digital model of the building system can be created for the location of the asset (e.g., floor that contains the air controller).

In some cases, the digital model can include portions of the building that include system level components associated with the asset. For example, the digital model can include a roof-top air handling unit, ducting to and from the air controller, electrical components, and building structural components associated with the system. Creating partial building models may increase the computational efficiency of the system by reducing the size and/or complexity of the digital models.

At operation 408, the process 400 can include extracting, from a set of asset schemas, a hierarchical, part_of, or member_of relationship between the asset categories and asset instances, assets that represent assemblies comprised of assets, and system level components. The building data management system can use schemas to define relationships between asset and system level components and building structural components as described herein.

At operation 410, the process 400 can include generating an interactive visual representation of the building. The interactive visual representation can be a three-dimensional model of the building structural components that are overlayed with a visual representation of the asset and visual representations for the other system level components. For example, the three-dimensional model of the building structural components can include geometrically accurate solid, surface, or other components that display the relative positioning of assets, systems, and other components with respect to the building’s structural features.

In some cases, the three-dimensional model can include CAD files and/or BIMs that define properties and/or relationships of the displayed components. Additionally or alternatively, the three-dimensional model can include drawings and/or renderings that provide a visual representation of an object, such as an asset, but may not define functional aspects of the object other than size and/or shape. In some cases, using renderings may increase the efficiency of the building data management system, for example, due to the smaller size and/or complexity of a visual rendering as compared to functional CAD file.

The interactive visual representation can include structured data files that define properties of the building, systems, and assets and an interrelation of these components for display on a client device. These relationships can allow the interactive visual representation to be manipulated using an operator interface. For example, a user may be able to rotate, pan, or otherwise move the interactive model within the operator interface.

In some cases, the user can select how different structural components, systems, assets, and/or other structures are displayed, such as changing a transparency of various components, hiding components, and so on as described herein. The operator interface can be configured to accept inputs related to the interactive model. As described herein, a user can select a specific asset, system, and/or other components, which can enable additional functions specific to a selected component. For example, if a user selects the air controller, the building data management system can display information related to the selected air controller, such as a digital link to a service manual, upstream and downstream assets, and/or systems related to the selected asset and so on.

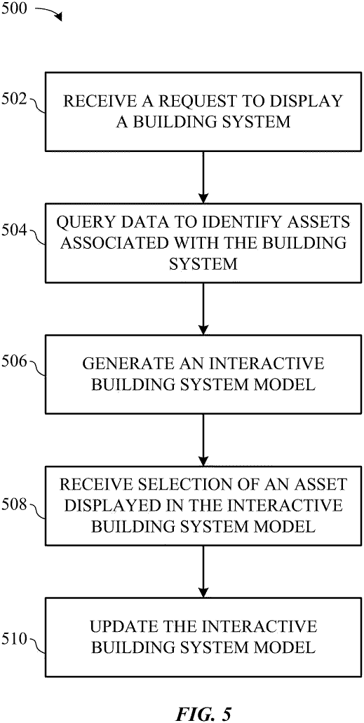

FIG. 5 shows an example process 500 for navigating building structures and systems. The process can be performed by the systems described herein such as the building data management system.

At operation 502, the process 500 can include receiving a request to display visual representation of the building system within a virtual building system model. In some cases, the request can be a request to view a specific building system and/or systems within a specific location within a building system model.

For example, a facility manager may be troubleshooting an issue, performing maintenance, or want to see all the systems that service a particular location. In this regard, the request can be categorically based to identify one or more assets based on their classification in a specific system and/or type of function that they perform. For example, the request can be to view all assets that are categorized as air handling units, or all assets that are categorized as circuit breakers. In some cases, the categories can include multiple different types of equipment.

For example, air-handling units can include roof-top units, ducting, air controllers, registers and so on. As another example, circuit breakers can include a main breaker and one or more sub-panels that are in the specified location. In some cases, the request can be received via the operator interface and include one or more filters with increasing levels of specificity. For example, under air handling units, the operator interface can include a list or other indication of the assets that fall under this classification. In the circuit breaker example, the operator interface can include a list of other indications of different types of circuit breakers, such as models, class of breakers, specific assets, and so on.

In some cases, the assets and systems that are shown are assets and/or systems that are within a location specified within the request. For example, the request can specify a specific floor, zones, rooms, set of floors, or other suitable sub-section of the building.

At operation 504, the process 500 can include querying the database to identify assets that satisfy the building system type and the building system location. The building data management system can retrieve asset information for assets meeting the type and/or location criteria. For example, in response to a request for all air handling units located on the fourth floor, the building data management system can be configured to retrieve asset information for the subset of assets and/or their related systems.

At operation 506, the process 500 can include using the building system location to generate a digital model of the building system, as described herein. In some cases, the digital model can be a model of the entire building. In other cases, the digital model can be a portion of the building, such as structural components related to a location specified in the request. In other cases, the digital model can be updated based on a user interaction/input. For example, the initial digital model can include a portion of the building corresponding to the location specified in the request. However, a user can interact with the operator interface to request an additional portion of the building to be displayed. For example, if the fourth floor is being displayed the user can select an option in the operator interface to view floors above and/or below the fourth floor, and in response the building data management system can generate additional model information for displaying these floors.

In some cases, operation 506 can also include retrieving structured data for the assets that satisfy the building system type and structured data for system level components associated with the assets. For example, the structured data can include asset specifications, input types, output types, BIM or CAD files and/or other two- or three-dimensional files, connections to input components and output components, and so on, as described herein. In some cases, the structured data can define geometric and/or functional relationships that define a hierarchical relationship of an asset within a system and in relation to other assets of the system.

Operation 506 can also include generating an interactive visual representation of the building system location comprising a three-dimensional model of the building structural components overlayed with visual representations of the assets and system level component associated with the assets and causing the display of the interactive visual representation on a client device, as described herein.

At operation 508, the process 500 can include receiving, from the client device, a selection of an asset of the assets that are displayed in the interactive visual representation of the building system location. A user interacting with the visual model may be troubleshooting an issue or performing maintenance operations and want to gather more information on a specific asset. For example, the user may be preparing to fix an air controller. The user can select the air controller in the operator interface to receive additional information about the air controller.

At operation 510, the process 500 can include, in response to the receiving the selection of the asset, the building data management system causes the selected asset to be displayed according to a first rendering schema (e.g., filtered view) and other assets of the assets to be displayed according to a second rendering schema. Continuing the air controller example, upon receiving the selection of the air controller, the operator interface can display the first controller in a shaded view and display other components, such as the building structural components in a transparent view. In some cases, selecting an asset can cause other components/assets of the same and/or related systems to be displayed according to the first rendering schema.

For example, ducting, a roof-top air handing unit, and one or more registers connected to the air controller can be shown in the shaded view, while other assets, systems, and structures in the interactive model are shown in a transparent view, and/or a hidden view setting. In this regard, the building data management system allows a user to request, search, or otherwise view and initial set of assets and then use the operator interface to navigate to specific assets, receive additional information about one or more assets and/or systems, and view functional and/or hierarchical information related to a specific asset or system.

In some cases, generating and displaying interactive models can be based on contextual factors such as a user identification, a role of a user, a type of request, a location of the user and so on. The building data management system can be configured to recognize and/or receive a user role and generate one or more interactive models based on the user’s role. Additionally or alternatively, the building data management system can be configured to determine a location of the user, for example based on location data associated with a client device and generate and display interactive models based on this location data.

As one example, the building data management system may be configured to generate and display different types of information based on the user’s role. The building management system may determine that a first user is assigned a role of a building engineer. Based on identifying this role, the building management system may generate and display interactive models contain systems and information that is routinely accessed by users assigned to this role. For example, in response to a request to display a visual model from an account associated with a building engineer role, the building management system may generate and display models that include data related to building HVAC, plumbing, electrical and/or other systems. As another example, if the request comes from a user account associated with a building manager role, the building management system may be configured to generate and display information related to that role, such as information about building efficiency, energy usage, system down-time, and so on. In this regard, the building management system may adapt the type of information provided to different set

As another example, the building management system may generate and display information that is relevant to first responders such as firefighters, paramedics, police and so on. For example, in response the building data management system can include a first responder mode such as a firefighter mode that generates and displays information relevant to firefighters. In response to activating a firefighting mode, the building management system can display information such as the location of activated fire alarms, one or more routes to these locations including routes that don’t include elevators, the locations of flammable or other hazardous materials such compressed gas lines, and so on. In this regard, the firefighters may be able to interact with the models generated by the building management system to plan routes, identify dangers such as flammable material storage, or other factors that would not otherwise be readily available. In some cases, building assets, systems, and/or other information relevant to first responders may be configures as part of the building system schemata. For example, in a hospital setting oxygen supply systems can be assigned a parameter such as flammable/combustible material parameter that can be used to identify these system in the emergency responder mode.

The building management system can have different first responder modes that are configured for different types of emergency services. For example, the building management system can have a function for police which may display different information that is displayed for firefighters. In a police function, the building management system may display information related to ingress and egress from the building, alternate routes to various locations, and so on.

In yet other examples, the building management system can be configured to tailor information to third-parties such as product manufactures, product distributors, insurance companies, and/or the like. For example, the building management system may be configured to display market data to product manufacturers, which may include information related to cost, reliability and other operational costs associated with specific assets and/or systems. In the case of insurance companies, the building management system may be configured to generate and provide data relevant to insuring different assets and/or systems.

Additionally or alternatively, the building management system may be configured to generate and display interactive models based on location data, such as location data associated with a client device. For example, the building management system may determine that a user is located on a third floor of a building and in a room that contains electrical systems. The building management system can use this information to display, on the user’s client device, an interactive model that shows the electrical system components at the user’s position (e.g., the third floor). The interactive model can display components and/or diagrams that are not visible to a user at that location, such as wiring diagrams, routing of electrical components within the buildings structure such as the ceiling, walls and so on. In this regard, the position data may be used to identify and determine relevant information that is displayed to a particular user.

In some cases, the building management system can be configured to generate and display augmented reality (AR) and/or virtual reality (VR) information about a building’s assets and systems. For example, a user can use AR/VR hardware such as goggles, glasses, and so on to view the location of building assets and their relationship to the various building systems. In some cases, the AR/VR displays can be from different perspectives, such as a perspective that would be viewed by a user. For example, a user standing on floor could look up towards the ceiling and the building management system can display, within and AR/VR system, HVAC components that are located behind the ceiling tiles.

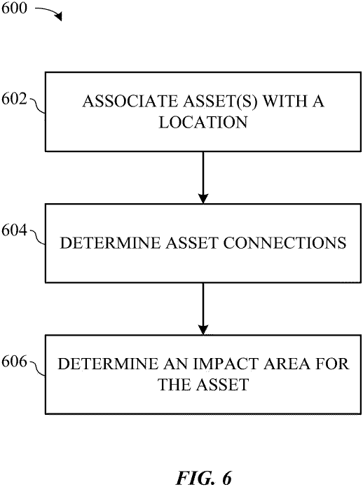

FIG. 6 shows an example process 600 for automatically defining location, system and asset relations for building structures and systems. The process 600 can be performed by the systems described herein such as the building data management system. The process 600 process can include analyzing BIM elements or other document data to define, location, system and equipment data relations for a buildings assets. In this regard, the building data management system can consume the BIM elements, document data, and/or other asset data and define interrelations (e.g., hierarchical relation, connections, functional relations, etc.) of a building assets and systems. The defined interrelations are generated by the building analysis consuming the model data and deriving relationships between various assets, which may not require manual definitions from an external source, such as manually defined schemas.

At operation 602, the process 600 includes associating one or more of a building’s assets with a location in the building system. This can include extracting three-dimensional geometry for an asset and three-dimensional geometry for a building location of the asset, which can be used to define the location of the asset in relation to the building’s structural elements, other assets and/or building systems. During this operation, an asset may have a defined location within the building system and relative to other structures, assets and/or systems, but the asset may not have a defined functional relationships with respects to other assets and/or systems.

At operation 604, the process 600 includes determining an asset’s connections to the buildings structures, other assets and/or buildings systems. This can include the building data management system defining the assets connections to upstream and downstream assets using geometry from the asset, connectors to the asset and the relation to other assets. For example, the building data management system can match positional coordinates (e.g., three-plane coordinate data) of assets and connector elements to determine other assets that the asset is connected to and the relationship of an asset to one or more building systems. The building data management system may determine that the asset is connected upstream to a roof-top unit and connected downstream to one or more ducting elements. Based on determining these connections and the assets location, the building data management system can derive that the asset is an air handling unit.

At operation 606, the process 600 can include determining an impact area for the asset. The impact area can include areas, other assets, downstream components or other spaces and/or components that are dependent on the asset. Continuing with the air handling example, once the connections between the air handling unit and its downstream components have been derived, the building data management system can use these derived relationships to determine locations and/or downstream components for the air handling unit. For example, the building data management system can identify the downstream ducting attached to the air handling unit and determine, based on a location of the ducting within the building system, which areas of the building are services by the air handling unit. The service area for the asset can be defined as an attribute of the asset such as a location based attribute. As assets and systems are analyzed by the building management system based on their location and connections, the identified connections and derived service area can be used to assign hierarchical and/or system relationships to the assets (e.g., defined as asset attributes in the building system schemas). For example, the connections and/or service area for the air handling unit can be used to assign the air handling unit system level attributes, which can identify the asset as belonging to a specific HVAC sub-system that services a specific portion of the building. In this regard, using the location and/or geometry data (e.g., position coordinates) the building management system can identify a specific asset and/or its interrelation to other assets and systems within a building.

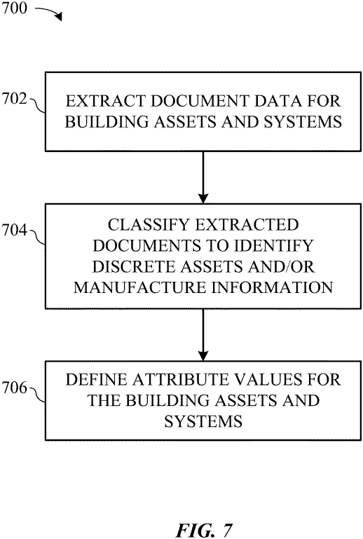

FIG. 7 shows an example process 700 for automatically extracting, classifying and defining attribute values for building structures and systems. The process 700 can be performed by the systems described herein such as the building data management system. In some cases, the building data management system can be configured to consume the various building systems data generated during planning and construction of a building system such as BIM data, asset information and system information, and normalize that data to generate a unified building data set for the building system.

At handover, a building owner and may receive a variety of documents, files and/or other building information. In many cases, each of these data sources can include different, and often overlapping sets of data regarding the building system. The building data management system can be configured to identify a document type, title, or other information about the document, classify and group documents based on relationships such as system relationships, hierarchical and/or service area relationships. The building data management system can inventory and identify assets contained within the various documents and/or files, and extract attributes such as system attributes for the identified assets. The process 700 outlines operations that can be used to perform one or more of the operations that are used to analyze documents, files and/or other information about the building.

At 702, the process 700 can include extracting document data for building assets and systems. The building analysis can include a data extraction engine that consumes the building system documents and identifies asset information such as asset types, names, model information, manufacturing information and so on. Additionally or alternatively, the extraction engine can extract system information such as system types, hierarchical relationship such as upstream and downstream connections, sub-systems, areas services by a system and/or subsystem and so on. In some cases, the extraction engine can use machine learning methods to process the documents and extract the document data for the building assets or system. For example machine learning can be used to identify and/or classify specific types of building system documents, such as identifying building structural documents, and other building systems such as mechanical systems, electrical systems, plumbing systems and the like or combinations thereof. In some embodiments, the building data management system is configured with a machine learning model that analyzes the building system data to identify or otherwise label specific assets and/or system located throughout the building.

It may be appreciated that a machine learning model is merely one example machine learning architecture or pattern identification technique, and that other embodiments may be implemented with additional or alternative pattern recognition, feature localization, or feature classification techniques such as textual identification and processing. Similarly, it may be appreciated that operations of feature localization (e.g., finding a location of an asset), feature labeling (e.g., identifying a type or classification of an asset), and the like may be performed in whole or in part without leveraging machine learning. For example, auto or cross correlation may be used in certain embodiments for both feature localization or identification. Accordingly, although it is appreciated that many implementations are possible (some of which may leverage machine learning and some of which may not).

At step 704, the process 704 can include classifying the extracted documents to identify discrete assets and/or manufacturer information associated with an asset. For example, the building data management system can analyze the documents to identify attributes such as a product category (e.g., type of assets, associated system(s), and/or the like). This can include analyzing the documents to determine general performance requirements for an asset, product requirements, and/or installation requirements. Additionally or alternatively, classifying the extracted documents can include matching an asset to identify a specific product including model information, manufacturing information, and so on. This can be accomplished by matching information from the extracted documents to specific assets in the building. Additionally or alternatively, learning algorithms can be implemented that provide schema function that account for factors such as synonyms, acronyms, spelling differences and so on for the match terms. In this regard, the processed documents can be associated with specific asset information for assets located within a build system.

At step 706, the process can include defining the attribute values for the building assets and systems. This can include obtaining information from the extracted documents and using that information to define a specific attribute for one or more assets.

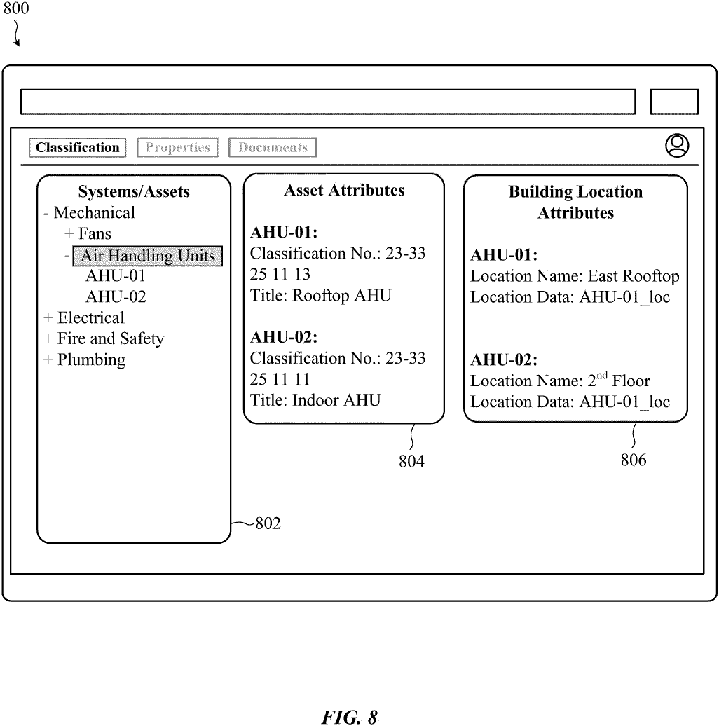

FIG. 8 shows an example user interface 800 for defining assets and system schemas for a building system model. The user interface 800 can be used to define relationships between assets and/or systems and building components and locations. These relationships can be used to create one or more facility data specifications that specifies the asset and system schemas for a facility, the attribute value pairs that qualify the data for processing, and the relations between assets, systems, building locations, and document types. In addition, the facility data specification can include a classification schema, the relations between classifications and assets, and the mappings between schema assets, internal data model(s), and the data models of partner systems.

In some cases, the user interface 800 can include a listing of systems and/or assets 802 that will be modeled by the building data management system, system and/or asset attribute information 804 and location data 806 for a building or facility that contain the systems and assets. The user interface 800 can be used to define relationships between the set of asset and/or systems 802, attributes of the systems/assets 804, the location data 806 for the building, and relevant document types. For example, a first asset can include an air handling unit (e.g., AHU-01), and be associated with asset and/or system schemas, which are used to access information about the particular air handling unit (AHU-01). The user interface 800 can include an interface such as the attribute information 804 interface for defining attribute data for the air handling unit (AHU-01) such as an omni class classification number, title for the asset, any other suitable attributes, and related document types for the asset category, including product submittals, training manuals, warranties, etc. The user interface 800 can also include the location data 806 interface, which can relate the schema data for the air handling unit (AHU-01) to specific location data. For example, the location data can include location name that indicates a general location of the system and/or asset and location data such as a data file that contains information about the spatial positioning of the asset relative to the building’s structural components, systems and/or other assets. In this regard, the association between the air handling unit (e.g., AHU-01)and the location data can be used to qualify the schema data for processing, and define the relations between the assets, systems, and building locations within the building system model.

These foregoing embodiments depicted in FIGS. 1-8 and the various alternatives thereof and variations thereto are presented, generally, for purposes of explanation, and to facilitate an understanding of various configurations and constructions of a system, such as described herein. However, it will be apparent to one skilled in the art that some of the specific details presented herein may not be required in order to practice a particular described embodiment, or an equivalent thereof.

Thus, it is understood that the foregoing and following descriptions of specific embodiments are presented for the limited purposes of illustration and description. These descriptions are not targeted to be exhaustive or to limit the disclosure to the precise forms recited herein. To the contrary, it will be apparent to one of ordinary skill in the art that many modifications and variations are possible in view of the above teachings.

Furthermore, it may be appreciated that as used herein, the phrase “at least one of” preceding a series of items, with the term “and” or “or” to separate any of the items, modifies the list as a whole, rather than each member of the list. The phrase “at least one of” does not require selection of at least one of each item listed; rather, the phrase allows a meaning that includes at a minimum one of any of the items, and/or at a minimum one of any combination of the items, and/or at a minimum one of each of the items. By way of example, the phrases “at least one of A, B, and C” or “at least one of A, B, or C” each refer to only A, only B, or only C; any combination of A, B, and C; and/or one or more of each of A, B, and C. Similarly, it may be appreciated that an order of elements presented for a conjunctive or disjunctive list provided herein should not be construed as limiting the disclosure to only that order provided.

One may appreciate that although many embodiments are disclosed above, that the operations and steps presented with respect to methods and techniques described herein are meant as exemplary and accordingly are not exhaustive. One may further appreciate that alternate step order or fewer or additional operations may be required or desired for particular embodiments.

Although the disclosure above is described in terms of various exemplary embodiments and implementations, it should be understood that the various features, aspects and functionality described in one or more of the individual embodiments are not limited in their applicability to the particular embodiment with which they are described, but instead can be applied, alone or in various combinations, to one or more of the some embodiments of the invention, whether or not such embodiments are described and whether or not such features are presented as being a part of a described embodiment. Thus, the breadth and scope of the present invention should not be limited by any of the above-described exemplary embodiments but is instead defined by the claims herein presented.

In addition, it is understood that organizations and/or entities responsible for the access, aggregation, validation, analysis, disclosure, transfer, storage, or other use of private data such as described herein will preferably comply with published and industry-established privacy, data, and network security policies and practices. For example, it is understood that data and/or information obtained from remote or local data sources, only on informed consent of the subject of that data and/or information, should be accessed aggregated only for legitimate, agreed-upon, and reasonable uses.

In addition, the foregoing examples and description of instances of purpose-configured software, whether accessible via API as a request-response service, an event-driven service, or whether configured as a self-contained data processing service are understood as not exhaustive. In other words, a person of skill in the art may appreciate that the various functions and operations of a system such as described herein can be implemented in a number of suitable ways, developed leveraging any number of suitable libraries, frameworks, first or third-party APIs, local or remote databases (whether relational, NoSQL, Graph, or other architectures, or a combination thereof), programming languages, software design techniques (e.g., procedural, asynchronous, event-driven, and so on or any combination thereof), and so on. The various functions described herein can be implemented in the same manner (as one example, leveraging a common language and/or design), or in different ways. In many embodiments, functions of a system described herein are implemented as discrete microservices, which may be containerized or executed/instantiated leveraging a discrete virtual machine, that are only responsive to authenticated API requests from other microservices of the same system. Similarly, each microservice may be configured to provide data output and receive data input across an encrypted data channel. In some cases, each microservice may be configured to store its own data in a dedicated encrypted database; in others, microservices can store encrypted data in a common database; whether such data is stored in tables shared by multiple microservices or whether microservices may leverage independent and separate tables/schemas can vary from embodiment to embodiment. As a result of these described and other equivalent architectures, it may be appreciated that a system such as described herein can be implemented in a number of suitable ways. For simplicity of description, many embodiments that follow are described in reference to an implementation in which discrete functions of the system are implemented as discrete microservices. It is appreciated that this is merely one possible implementation.

What is claimed is:

1. An interface processing system for displaying interrelated hierarchical building system models, comprising:
a memory allocation defined by:
a data store storing an executable asset; and
a working memory allocation; and
a processor allocation configured to load the executable asset from the data store into the working memory allocation to instantiate an instance of a building management service configured to:
receive from a client application executing an operator interface on a client device, a request to display a visual representation of an asset located in a building within a virtual building system model;
query an asset database comprising structured data associated with the asset, to determine location data for the asset and system level components associated with the asset;
use the location data to generate a digital model of a building system location associated with the asset, the digital model comprising a three-dimensional model of building structural components;
retrieve model data for the asset and model data for the system level components;
extract, using a set of asset schemas, a hierarchical relationship between the asset and the system level components;
generate, an interactive visual representation of the building system location comprising the three-dimensional model of the building structural components overlayed with visual representations of the asset and the system level components; and
send, to the client application executing on the client device, an interactive data set for displaying the interactive visual representation in the operator interface.

2. The interface processing system of claim 1, wherein:
receiving the request to display the visual representation of the asset comprises an asset identifier associated with the asset; and
the asset identifier is used to retrieve the model data for the asset.

3. The interface processing system of claim 1, wherein retrieving the model data for the system level components comprises identifying input components to the asset and output components from the asset.

4. The interface processing system of claim 3, wherein:
identifying the input components comprises identifying a breaker circuit associated with the asset; and
identifying the output components comprises identifying a ventilation system component that is fed by the asset.

5. The interface processing system of claim 1, wherein querying the asset database to determine location data for the asset and system level components associated with the asset comprises using three-dimension geometry for the asset to determine a relationship of the asset to the location and system level components.

6. The interface processing system of claim 1, further comprising:
receiving a selection of a sub-system of the system level components; and
in response to receiving the selection of the sub-system, generating a three-dimensional model to render the sub-system in a first display scheme and other sub-systems of the system level components in a second display scheme.

7. The interface processing system of claim 6, wherein:
the first display scheme comprises a solid view of the sub-system; and
the second display scheme comprises a partially transparent view of the other sub-systems.

8. The interface processing system of claim 6, wherein extracting the hierarchical relationship between the asset and the system level components comprises analyzing the set of asset schemas to determine input components to the asset and output components from the asset.

9. A method for generating interrelated hierarchical building system models, the method comprising:
receiving a request to display a visual representation of an asset located in a building within a virtual building system model;
querying an asset database to determine location data for the asset and a system level components associated with the asset;
using the location data to generate a digital model of the building at the asset location, the digital model comprising a three-dimensional model of building structural and architectural components;
retrieving model data for the asset and model data for the system level components;
extracting, using a set of asset schemas, a hierarchical relationship between the asset and the system level components; and
generating an interactive visual representation of the building comprising the three-dimensional model of the building structural and architectural components overlayed with a visual representation of the asset and visual representations for the system level components.

10. The method of claim 9, wherein querying the asset database to determine the location data for the asset comprises determining a location of the asset with respect to the building structural components.

11. The method of claim 10, wherein generating the interactive visual representation of the building comprises indicating the location of the asset within the interactive visual representation.

12. The method of claim 9, wherein:
generating the interactive visual representation comprises generating one or more layers comprising:
a first layer comprising the three-dimensional model of the building structural components;
a second layer comprising the visual representation of the asset; and
one or more additional layers comprising the visual representations for the system level components.

13. The method of claim 12, wherein the one or more additional layers are independently viewable.

14. The method of claim 9, wherein:
the system level components include input components to the asset and output components from the asset; and
the hierarchical relationship between the asset and the system level components specifies which system level components are the input components and which system level components are the output components.

15. The method of claim 9, wherein:
the visual representation of the asset is based on three-dimensional model data for the asset; and
the visual representation of the system level components is based on three-dimensional model data for the system level components.

16. The method of claim 9 further comprising:
identifying model information associated with the asset; and
retrieving, from the asset database, a digital service manual for the asset; wherein
the interactive visual representation comprises an option to view the digital service manual for the asset.

17. A method for generating a structured data model used to display an interactive hierarchical model of a building system, the method comprising:
receiving a request to display a visual representation of the building system within a virtual building system model, the request comprising a building system type and a building system location;
querying an asset database to identify assets that satisfy the building system type and the building system location;
using the building system location to generate a digital model of the building system, the digital model comprising a three-dimensional model of building structural components;
retrieving structured data for the assets that satisfy the building system type and structured data for system level components associated with the assets;
generating an interactive visual representation of the building system location comprising the three-dimensional model of the building structural components overlayed with visual representations of the assets and the system level components associated with the assets;
causing display of the interactive visual representation on a client device;
receiving, from the client device, a selection of an asset of the assets displayed in the interactive visual representation of the building system location; and
in response to the receiving the selection of the asset, causing:
the asset to be displayed according to a first rendering schema; and
other assets of the assets to be displayed according to a second rendering schema.

18. The method of claim 17, wherein:
the first rendering schema comprises a solid view of the asset; and
the second rendering schema comprises at least a partially transparent view.

19. The method of claim 17, further comprising:
in response to the receiving the selection of the asset, retrieving, from the asset database, a digital service manual for the asset; and
causing the client device to display an option to view the digital service manual.

20. The method of claim 17, further comprising:
Identifying the system level components associated with the assets; and
causing the system level components associated with the assets to be displayed according to the first rendering schema.
